(19) United States
(12) Patent Application Publication
(10) Pub. No.: US 2025/0040202 A1
(43) Pub. Date: Jan. 30, 2025

(54) METHODS AND DEVICES FOR VERTICAL CONNECTION WITH INTERNAL EPITAXIAL STRUCTURE

(71) Applicant: Tokyo Electron Limited, Tokyo (JP)

(72) Inventors: Mark I. GARDNER, Austin, TX (US); Henry Jim FULFORD, Marianna, FL (US)

(73) Assignee: Tokyo Electron Limited, Tokyo (JP)

(21) Appl. No.: 18/227,059

(22) Filed: Jul. 27, 2023

(51) Int. Cl. H01L 29/06; H01L 27/092; H01L 29/10; H01L 29/66; H01L 29/786

(52) U.S. Cl. CPC H01L 29/0684; H01L 27/092; H01L 29/0649; H01L 29/1029; H01L 29/66545; H01L 29/78696

(57) ABSTRACT

Semiconductor devices and corresponding methods of manufacture are disclosed. The devices may include a first epitaxial structure disposed below a dielectric pillar, a second epitaxial structure disposed above the first epitaxial structure and around the dielectric pillar, a third epitaxial structure disposed above the second epitaxial structure and around the dielectric pillar, and a fourth epitaxial structure disposed above the third epitaxial structure and around the dielectric pillar. The second and third epitaxial structures may each have a portion inwardly extending toward a central axis of the dielectric pillar.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits.

### SUMMARY

The techniques described herein include methods and devices for 3D fabrication of semiconductor devices. Specifically, techniques disclosed herein include inward epitaxial growth of source/drain structures and connecting the source/drain structures using vertical structures.

One aspect of the present disclosure is directed to a semiconductor device. The semiconductor device may include a first epitaxial structure disposed below a dielectric pillar, a second epitaxial structure disposed above the first epitaxial structure and around the dielectric pillar, a third epitaxial structure disposed above the second epitaxial structure and around the dielectric pillar, and a fourth epitaxial structure disposed above the third epitaxial structure and around the dielectric pillar. The second and third epitaxial structures may each have a portion inwardly extending toward a central axis of the dielectric pillar.

In some examples, the semiconductor device may include a first conductor structure extending in a vertical direction through the dielectric pillar, a second conductor structure extending in the vertical direction through the dielectric pillar, a third conductor structure extending in the vertical direction through the dielectric pillar, and a fourth conductor structure extending in the vertical direction.

In some examples, the first conductor structure may be in contact with the first epitaxial structure, the second conductor structure may be in contact with the portion of the second epitaxial structure, the third conductor structure may be in contact with the portion of the third epitaxial structure, and the fourth may be in contact with the fourth epitaxial structure.

In some examples, the portion of the second epitaxial structure may have a first lateral distance, and the portion of the third epitaxial structure may have a second lateral distance. The first lateral distance may be substantially greater than the second lateral distance.

In some examples, the semiconductor device may include a dielectric spacer disposed above the third epitaxial structure and around an upper portion of the dielectric pillar.

In some examples, the dielectric spacer is surrounded by the fourth epitaxial structure.

In some examples, the semiconductor device may include a first semiconductor structure surrounding the dielectric pillar and disposed between the first epitaxial structure and the second epitaxial structure, and a second semiconductor structure surrounding the dielectric pillar and disposed between the third epitaxial structure and the fourth epitaxial structure.

In some examples, the semiconductor device may include a first gate structure further surrounding the first semiconductor structure, and a second gate structure further surrounding the second semiconductor structure.

In some examples, the first semiconductor structure, the first gate structure, the first epitaxial structure, and the second epitaxial structure may collectively form a first transistor, and the second semiconductor structure, the second gate structure, the third epitaxial structure, and the fourth epitaxial structure may collectively form a second transistor.

In some examples, the first transistor may have a first conductivity, and the second transistor may have a second, opposite conductivity.

Yet another aspect of the present disclosure is directed to a semiconductor device. The semiconductor device may include a first transistor and a second transistor. The first transistor may include a first source/drain structure formed in a disc shape, and a second source/drain structure formed in a ring shape and disposed above the first source/drain structure. The second transistor may include a third source/drain structure formed in the ring shape and disposed above the second source/drain structure and a fourth source/drain structure formed in the ring shape and disposed above the third source/drain structure. The second source/drain structure may have a first inner radius, the third source/drain structure may have a second inner radius, and the fourth source/drain structure may have a third inner radius. The first inner radius may be less than the second inner radius, and the second inner radius may be less than the third inner radius.

In some examples, the first transistor may have a first conductivity, and the second transistor may have a second conductivity opposite to the first conductivity.

In some examples, the first transistor may include a first channel structure formed in the ring shape and disposed between the first source/drain structure and the second source/drain structure, and the second transistor may include a second channel structure formed in the ring shape and disposed between the third source/drain structure and the fourth source/drain structure.

In some examples, the first transistor may include a first gate structure formed in the ring shape and surrounding the first channel structure, and the second transistor may include a second gate structure formed in the ring shape and surrounding the second channel structure.

In some examples, the device may include a first conductor structure extending in a vertical direction to be in electrical connection with the first source/drain structure, a second conductor structure extending in the vertical direction to be in electrical connection with the second source/drain structure, a third conductor structure extending in the vertical direction to be in electrical connection with the third source/drain structure, and a fourth conductor structure extending in the vertical direction to be in electrical connection with the fourth source/drain structure.

In some examples, the first to fourth conductor structures may be laterally spaced from one another.

In some examples, the first to fourth source/drain structures may be each an epitaxial structure.

Yet another aspect of the present disclosure is directed to a method for microfabrication. The method may include forming a first epitaxial structure, a second epitaxial structure, a third epitaxial structure, and a fourth epitaxial structure spaced from one another along a vertical direction, each of the first to fourth epitaxial structure formed in a disc shape. The first epitaxial structure may be disposed below a first channel pillar, the second epitaxial structure may be disposed above the first channel pillar and below the third epitaxial structure, the third epitaxial structure may be disposed below a second channel pillar, and the fourth epitaxial structure may be disposed above the second channel pillar. The method may include removing a central portion of the first channel pillar and a central portion of the second channel pillar, thereby forming the second to fourth epitaxial structures each in a ring shape. The method may include inwardly extending the second epitaxial structure. The method may include inwardly extending the third epitaxial structure. The method may include forming a first conductor structure, a second conductor structure, a third conductor structure, and a fourth conductor structure to be in contact with the first epitaxial structure, the second epitaxial structure, the third epitaxial structure, and the fourth epitaxial structure, respectively. Each of the first to fourth conductor structures may extend along the vertical direction.

In some examples, the method may include, prior to the step of inwardly extending the second epitaxial structure, forming a dielectric pillar to overlay the first epitaxial structure and cover an inner sidewall of the second epitaxial structure, forming a first dielectric spacer to cover respective inner sidewalls of the third epitaxial structure and the fourth epitaxial structure, and removing a portion of the dielectric pillar to expose the inner sidewall of the second epitaxial structure.

In some examples, the method may include, following the step of inwardly extending the second epitaxial structure and prior to the step of inwardly extending the third epitaxial structure, removing the first dielectric spacer, extending the dielectric pillar to cover the respective inner sidewalls of the third epitaxial structure and the fourth epitaxial structure, removing another portion of the dielectric pillar to expose the inner sidewall of the fourth epitaxial structure, forming a second dielectric spacer to cover the inner sidewall of the fourth epitaxial structure, and removing yet another portion of the dielectric pillar to expose the inner sidewall of the third epitaxial structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of a method for manufacturing a semiconductor device, according to some embodiment.

FIGS. 2-13 illustrate cross-sectional views of a semiconductor device, made by the method shown in FIG. 1, during various stages of fabrication, according to some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for vertical connection with internal epitaxial structures. Specifically, techniques disclosed herein include inward growth (e.g., 3D internal epitaxial source/drain differential growth) of structures and connecting the structures using vertical structures interior of the device with access from the top of the device. Using such a vertical transistor architecture allows for an enhanced 3D density for high density circuits. Advantages of techniques disclosed herein include that all interior vertical connections can be achieved with one masking layer using indent etch filling and horizontal spacer isolation deposition technique, thereby reducing manufacturing costs and process flows.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

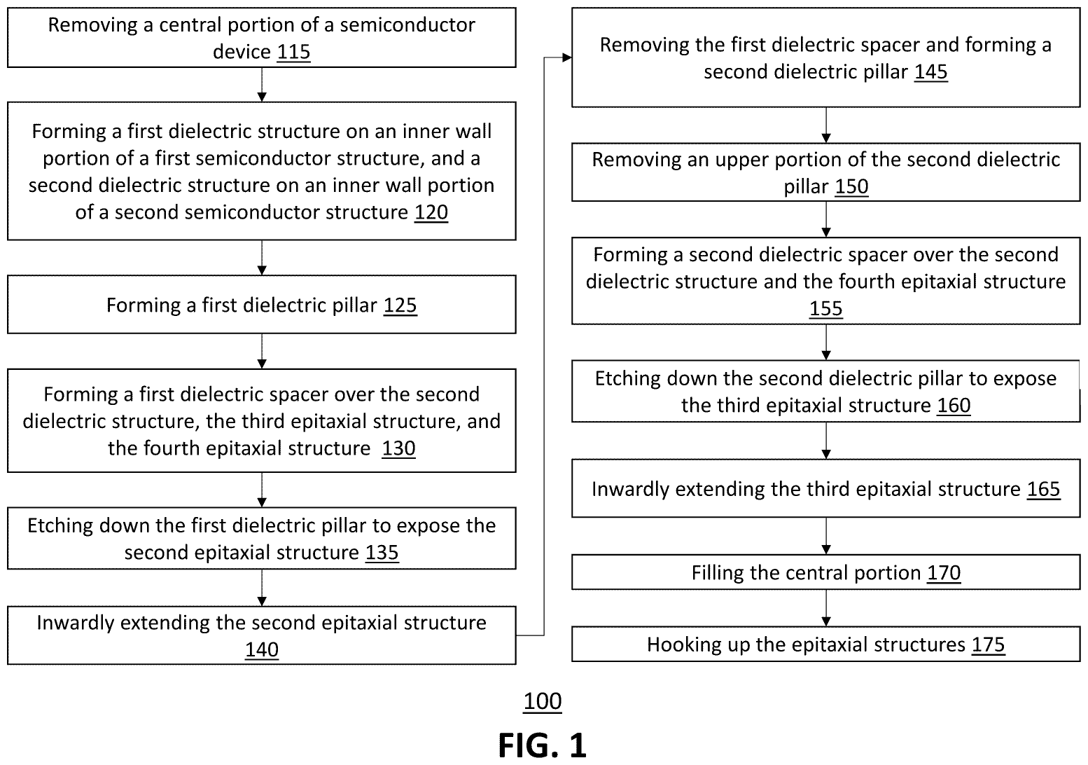

FIG. 1 illustrates a flow chart of a method 100 for fabricating a semiconductor device, in accordance with some embodiments. It is noted that the method 100 is merely an example and is not intended to limit the present disclosure. Accordingly, it is understood that additional operations may be provided before, during, and after the method 100 of FIG. 1, that any operation may be omitted, and that some other operations may only be briefly described herein.

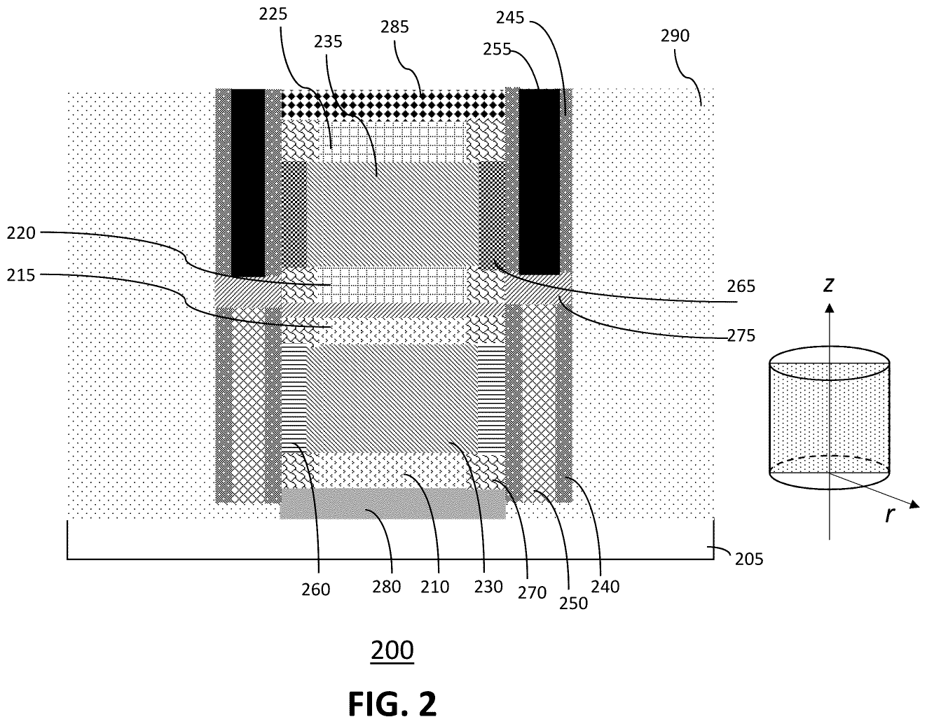

In various embodiments, operations of the method 100 may be associated with cross-sectional views of an example structure at various fabrication stages as shown in FIGS. 2 to 13, which will be discussed in further detail below. It should be understood that the structure, shown in FIGS. 2 to 13, may include a number of other structures, while remaining within the scope of the present disclosure.

In brief overview, the method 100 starts with operation 115 of removing a central portion of a semiconductor device. The method 100 continues to operation 120 of forming a first dielectric structure on an inner wall portion of a first semiconductor structure, and a second dielectric structure on an inner wall portion of a second semiconductor structure. The method 100 continues to operation 125 of forming a first dielectric pillar. The method 100 continues to operation 130 of forming a first dielectric spacer over the second dielectric structure, the third epitaxial structure, and the fourth epitaxial structure. The method 100 continues to operation 135 of etching down the first dielectric pillar to expose the second epitaxial structure. The method 100 continues to operation 140 of inwardly extending the second epitaxial structure. The method 100 continues to operation 145 of removing the first dielectric spacer and forming a second dielectric pillar. The method 100 continues to operation 150 of removing an upper portion of the second dielectric pillar. The method 100 continues to operation 155 of forming a second dielectric spacer over the second dielectric structure and the fourth epitaxial structure. The method 100 continues to operation 160 of etching down the second dielectric pillar to expose the third epitaxial structure. The method 100 continues to operation 165 of inwardly extending the third epitaxial structure. The method 100 continues to operation 170 of filling the central portion. The method 100 continues to operation 175 of hooking up the epitaxial structures.

The method 100 can be performed on various semiconductor devices at various stages of manufacturing processes. FIG. 2 is a cross-sectional view of the semiconductor device 200, in accordance with some embodiments. Specifically, the semiconductor device 200 is shown as an example structure on which the method 100 can be performed. The semiconductor device 200 may be a cylindrical structure, and FIG. 2 is a cylindrical cross section of the semiconductor device 200 (e.g., the shaded area of the cylindrical coordinate shown in FIG. 2). The semiconductor device 200 can include various layers formed therein (e.g., ring layers, disc layers, cylinders, etc.). In some embodiments, the semiconductor device 200 may be a rectangular structure, in which various layers can be formed (e.g., rectangular ring/disc layers). Although depicted as cylindrical, shown in FIG. 2 is a non-limiting example of the semiconductor device 200, and the semiconductor device 200 may be in any shape, dimension, or symmetry.

Referring to FIG. 2, the semiconductor device 200 includes various layers and/or structures. The layers and/or structures formed in the semiconductor device 200 may include a substrate 205, a bottom cap structure 280, a first dielectric feature 270, a second dielectric feature 275, a first epitaxial structure 210, a first gate dielectric 240, a first gate structure 250, a first semiconductor structure 230, a first dopped semiconductor structure 260, a second epitaxial structure 215, a third epitaxial structure 220, a fourth epitaxial structure 225, a second semiconductor structure 235, a second dopped semiconductor structure 265, a second gate structure 255, a second gate dielectric 245, a top cap structure 285, and an isolation dielectric 290.

The various layers formed in the semiconductor device 200 can be manufactured/fabricated/processed to operate as a semiconductor device. For example, the semiconductor device 200 can be manufactured/fabricated/processed to operate as field effect transistors such as complementary field effect transistors, as described below with respect to FIG. 2 to FIG. 13.

With respect to FIG. 2 to FIG. 13, from the operation 115 to operation 175 of FIG. 1, various techniques for fabricating the semiconductor device 200 can be used. For example, any deposition/growth methods may be used to form various layers and structures, including but not limited to, chemical vapor deposition (CVD), physical vapor deposition (PVD), plasma enhanced CVD (PECVD), molecular beam epitaxy (MBE), metal organic CVD (MOCVD), or the like. For example, any etching methods (e.g., wet, dry; isotropic, anisotropic, etc.) may be used to remove a portion of formed layers or structures.

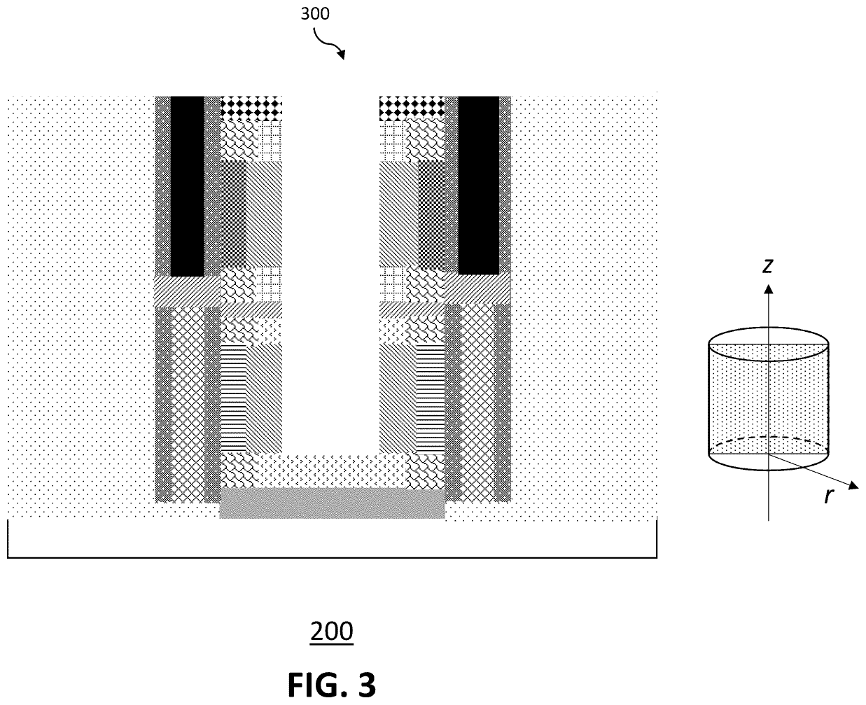

Corresponding to operation 115 of FIG. 1, FIG. 3 shows a cross-sectional view of the semiconductor device 200 in which a central portion 300 of the semiconductor device 200 is removed, in accordance with various embodiments. As shown in FIG. 3, at least a portion (e.g., a respective central portion) of the first semiconductor structure 230, the second epitaxial structure 215, the third epitaxial structure 220, the second dielectric feature 275, the second semiconductor structure 235, the fourth epitaxial structure 225, and the top cap structure 285 of the semiconductor device 200 are directionally etched, such that each of said layers forms a ring shape. To etch the central portion 300, a patternable layer (e.g., a photoresist material) can be formed over the surface of the semiconductor device 200. A patterned layer (not depicted) can define the central portion 300. The directional etching can be performed downward from the top surface of the semiconductor device 200 to the top surface of the first epitaxial structure 210 with the patterned layer defining the central portion 300. The central portion 300 of the semiconductor device 200 can be etched to the top surface of the first epitaxial structure 210. For example, the etchant can be timed to etch to the top surface of the first epitaxial structure 210, or the first epitaxial structure 210 can be non-reactive with the etchant. The photoresist material (or the patterned layer, the mask layer, etc.) can be stripped from the semiconductor device 200.

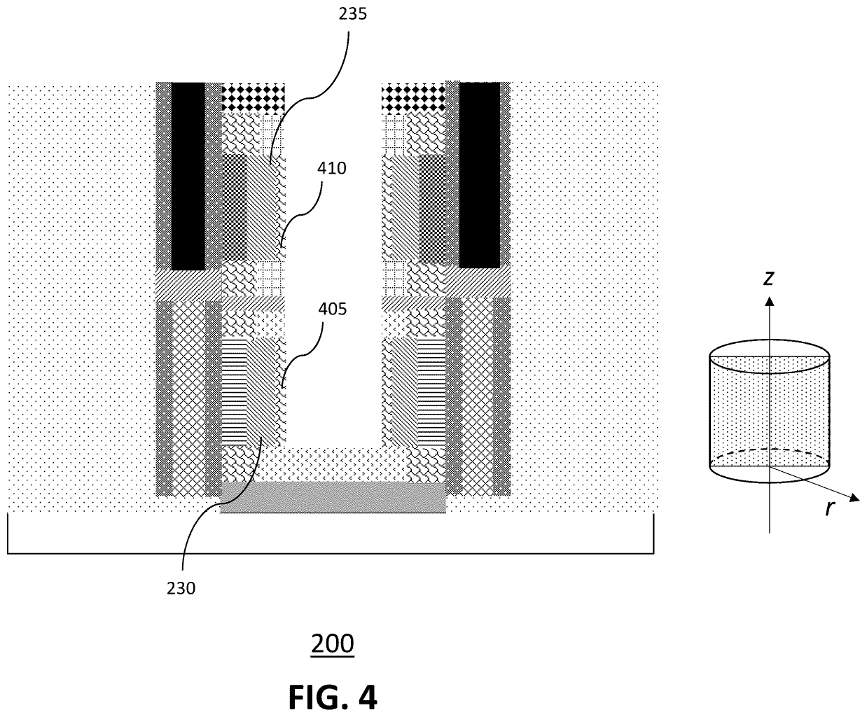

Corresponding to operation 120 of FIG. 1, FIG. 4 is a cross-sectional view of the semiconductor device 200 in which a first dielectric structure 405 is formed on an inner wall portion of a first semiconductor structure 230, and a second dielectric structure 410 is formed on an inner wall portion of a second semiconductor structure 235, in accordance with various embodiments. As shown in FIG. 4, the first semiconductor structure 230 and the second dielectric structure 410 are ring-shaped, formed by removing the respective central portion 300 of the first semiconductor structure 230 and the second semiconductor structure 235 (at operation 115). To form the first dielectric structure 405 and the second dielectric structure 410, the first semiconductor structure 230 and the second semiconductor structure 235 can be indent-etched (e.g., outward etching, +r direction), and materials for the first dielectric structure 405 and the second dielectric structure 410 can be deposited on the etched portion of the first semiconductor structure 230 and the second semiconductor structure 235, respectively. In some examples, where materials for the first dielectric structure 405 and the second dielectric structure 410 are deposited on an unwanted portion (e.g., other than the first semiconductor structure 230 and the second semiconductor structure 235), a directional etching can be performed on the semiconductor device 200 so as to remove the materials deposited on the unwanted portion. The first dielectric structure 405 and the second dielectric structure 410 can be used to prevent unwanted epitaxial growth on the first semiconductor structure 230 and the second semiconductor structure 235, respectively, in later steps.

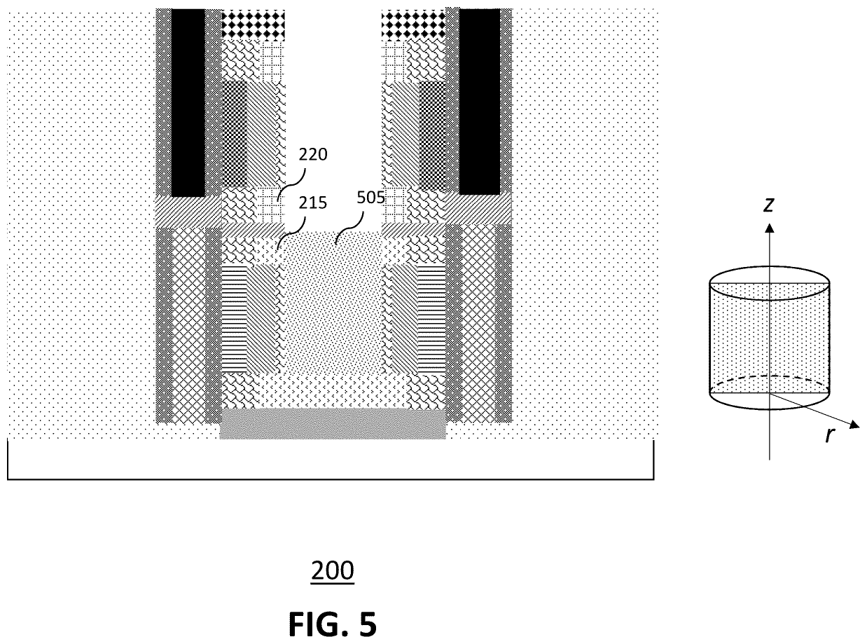

Corresponding to operation 125, FIG. 5 is a cross-sectional view of the semiconductor device 200 in which a first dielectric pillar 505 is formed, in accordance with various embodiments. To form the first dielectric pillar 505, dielectric material for the first dielectric pillar 505 can be deposited over the semiconductor device 200 (or selectively inside the central portion 300). The first dielectric pillar 505 can be formed from the top surface of the first epitaxial structure 210 upward to a portion between a second epitaxial structure 215 and a third epitaxial structure 220, where the second epitaxial structure 215 and the third epitaxial structure 220 are respectively ring-shaped, formed by removing the respective central portion 300 of the second epitaxial structure 215 and the third epitaxial structure 220 (at operation 115). The dielectric material for the first dielectric pillar 505 can be materials that allow for selective etching of the first dielectric pillar 505. For example, the materials for the first dielectric pillar 505 may be or include any oxide-based dielectrics, any nitride-based dielectrics, or any material with a high dielectric constant (e.g., high K dielectrics). Following the formation of the first dielectric pillar 505, the first dielectric pillar 505 can be etched and/or planarized. For example, the first dielectric pillar 505 can be directionally etched. For example, etchant(s) can be used that are selectively effective for etching the first dielectric pillar 505 (while not effective for etching the other materials/structures/layers).

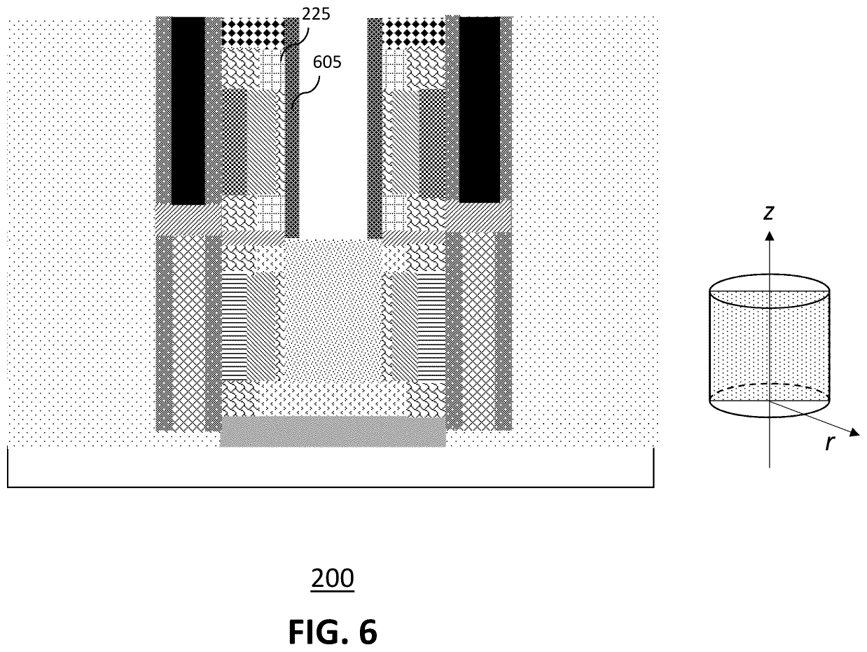

Corresponding to operation 130, FIG. 6 is a cross-sectional view of the semiconductor device 200 in which a first dielectric spacer 605 is formed over at least the second dielectric structure 410, the third epitaxial structure 220, and a fourth epitaxial structure 225, in accordance with various embodiments. For example, material for the first dielectric spacer 605 can be deposited over at least the second dielectric structure 410, the third epitaxial structure 220, and the fourth epitaxial structure 225. The fourth epitaxial structure 225 is ring-shaped, formed by removing the central portion 300 of the fourth epitaxial structure 225 (at operation 115).

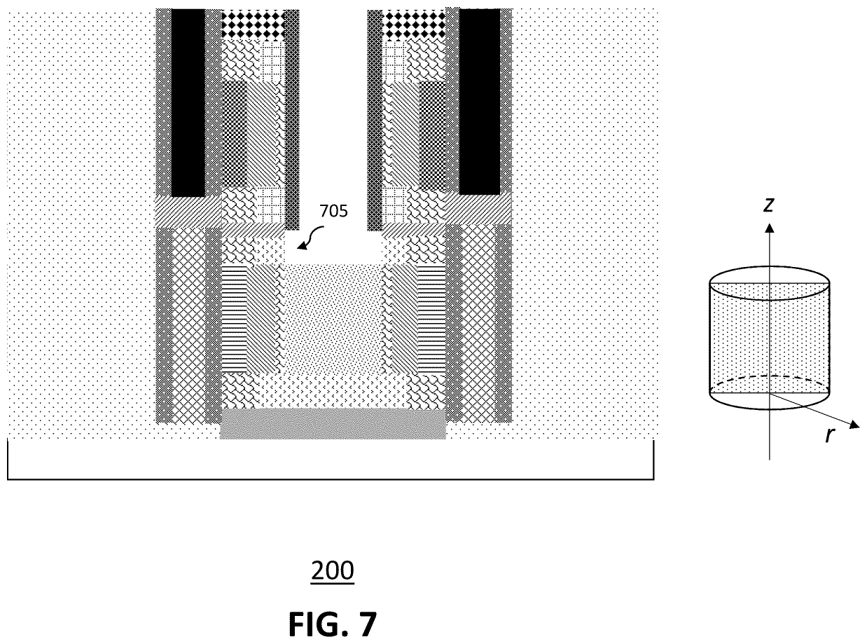

Corresponding to operation 135, FIG. 7 is a cross-sectional view of the semiconductor device 200 in which the first dielectric pillar 505 is etched down to expose the second epitaxial structure 215, in accordance with various embodiments. Since the material for the first dielectric pillar 505 can be selectively etched as discussed above, etchant(s) can be used that are selectively effective for etching the first dielectric pillar 505 (while not effective for etching the other materials/structures/layers). The etching process can be performed to form an opening 705 and expose the second epitaxial structure 215. For example, the etchant can be timed to etch to the bottom surface of the second epitaxial structure 215, or the top surface of the first dielectric structure 405.

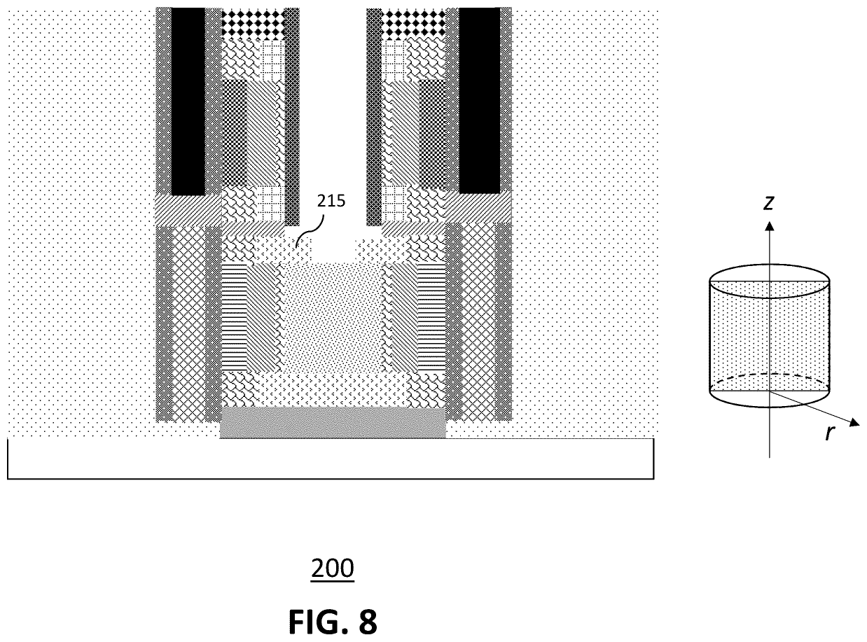

Corresponding to operation 140, FIG. 8 is a cross-sectional view of the semiconductor device 200 in which the second epitaxial structure 215 is extended inwardly, in accordance with various embodiments. As shown in FIG. 8, the second epitaxial structure 215 can be extended inwardly (e.g., −r direction) through the opening 705 by epitaxially growing the material for the second epitaxial structure 215, on the inner wall portion of the second epitaxial structure 215. As discussed above, various growth methods can be used. For example, MOCVD, PECVD, MBE, etc. can be used for the epitaxial growth of the material for the second epitaxial structure 215, on the inner wall portion of the second epitaxial structure 215.

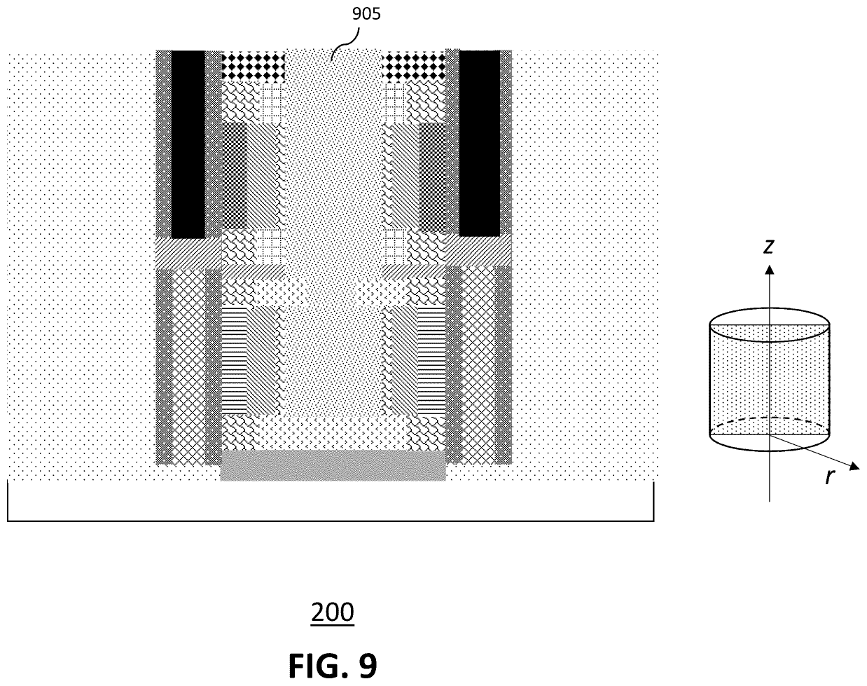

Corresponding to operation 145, FIG. 9 is a cross-sectional view of the semiconductor device 200 in which the first dielectric spacer 605 is removed and a second dielectric pillar 905 is subsequently formed, in accordance with various embodiments. The first dielectric spacer 605 can be etched, for example, by selectively etching the first dielectric spacer 605 using etchant(s) that are effective for etching the first dielectric spacer 605 while not affecting the other materials/structures/layers (e.g., without affecting the third epitaxial structure 220 and the fourth epitaxial structure 225). To form the second dielectric pillar 905, the dielectric material used for the first dielectric pillar 505 can be deposited as the material for second dielectric pillar 905, over the semiconductor device 200 (e.g., on the first dielectric pillar 505, inside the central portion 300). For example, the second dielectric pillar 905 can be deposited on the top surface of the first dielectric pillar 505 so as to form a continuous dielectric structure (e.g., the first dielectric pillar 505 and the second dielectric pillar 905) from the top surface of the first epitaxial structure 210 to the top surface of the semiconductor device 200.

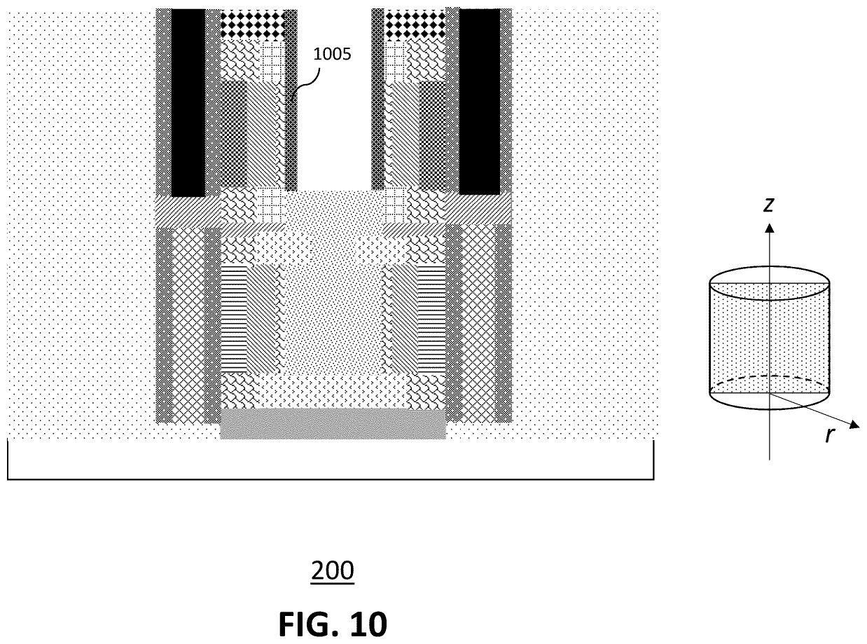

Corresponding to operation 150, FIG. 10 is a cross-sectional view of the semiconductor device 200 in which an upper portion of the second dielectric pillar 905 is etched down, in accordance with various embodiments. The second dielectric pillar 905 can be etched down by selectively etching the second dielectric pillar 905 or directionally etching the same (e.g., using a mask layer to protect the other materials/structures/layers, and subsequently stripping the mask layer). The second dielectric pillar 905 can be etched down to the top surface of the third epitaxial structure 220 or the bottom portion of the second semiconductor structure 235. (e.g., timed to etch to the top surface of the third epitaxial structure 220 or the bottom portion of the second semiconductor structure 235).

Corresponding to operation 160, and still referring to FIG. 10, a second dielectric spacer 1005 is formed over at least the second dielectric structure 410, the third epitaxial structure 220, and the fourth epitaxial structure 225, in accordance with various embodiments. For example, material for the second dielectric spacer 1005 can be deposited over at least the second dielectric structure 410, the third epitaxial structure 220, and the fourth epitaxial structure 225.

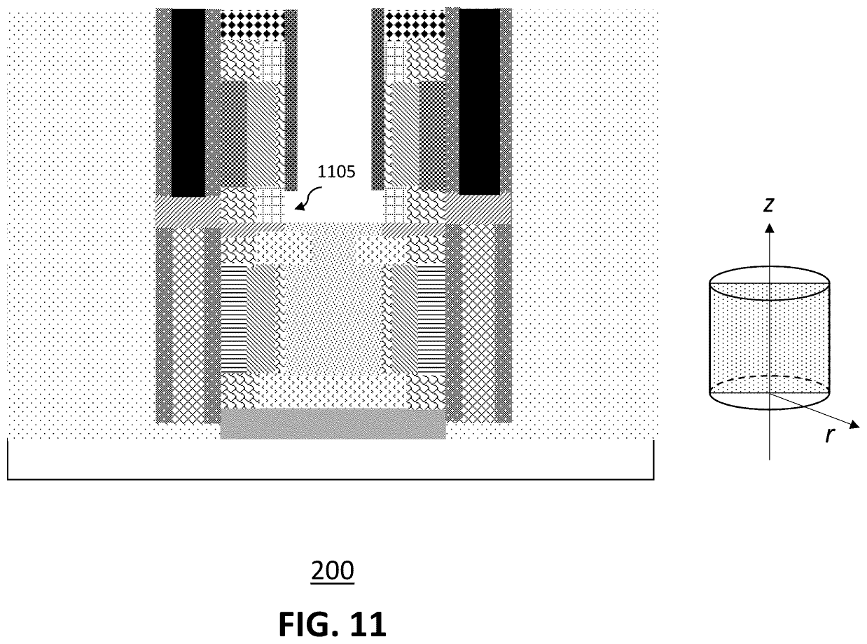

Corresponding to operation 160, FIG. 11 is a cross-sectional view of the semiconductor device 200 in which the second dielectric pillar 905 is etched down to expose the third epitaxial structure 220, in accordance with various embodiments. Since the material for the second dielectric pillar 905 can be selectively etched as discussed above, etchant(s) can be used that are selectively effective for etching the second dielectric pillar 905 (while not effective for etching the other materials/structures/layers). The etching process can be performed to form an opening 1105 and expose the third epitaxial structure 220. For example, the etchant can be timed to etch to the bottom surface of the 220.

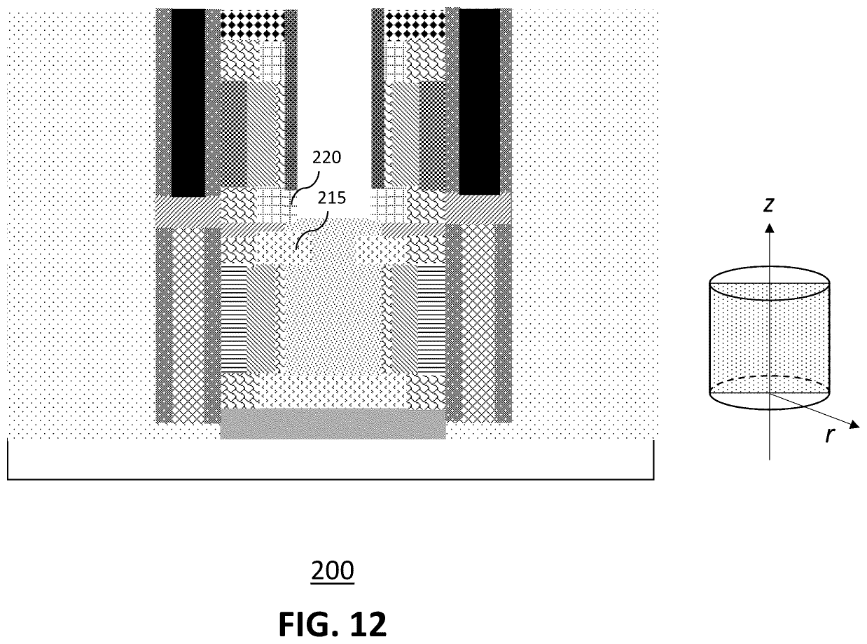

Corresponding to operation 165, FIG. 12 is a cross-sectional view of the semiconductor device 200 in which the third epitaxial structure 220 is extended inwardly, in accordance with various embodiments. As shown in FIG. 12, the third epitaxial structure 220 can be extended inwardly (e.g., −r direction) through the opening 1105 by epitaxially growing the material for the third epitaxial structure 220, on the inner wall portion of the third epitaxial structure 220. As discussed above, various growth methods can be used. For example, MOCVD, PECVD, MBE, etc. can be used for the epitaxial growth of the material for the second epitaxial structure 215, on the inner wall portion of the third epitaxial structure 220.

Referring to FIG. 12, at least a portion of the second epitaxial structure 215 can be seen when viewed from the top. That is, as shown in FIG. 12, an inner portion of the second epitaxial structure 215 is closer to the z-axis (e.g., central axis) than that of the third epitaxial structure 220 is. In some embodiments, the radial length (e.g., lateral distance in FIG. 12) of the second epitaxial structure 215 is substantially greater than the radial length (e.g., lateral distance in FIG. 12) of the third epitaxial structure 220.

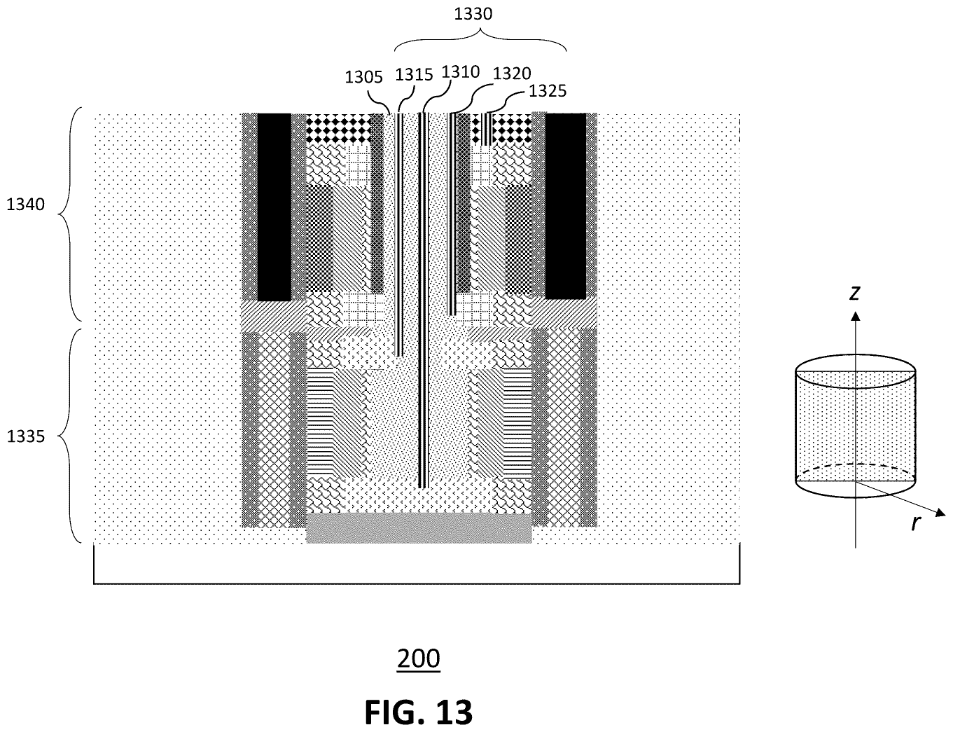

Corresponding to operation 170, FIG. 13 is a cross-sectional view of the semiconductor device 200 in which the central portion 300 is filled with the material for the second dielectric pillar 905, in accordance with various embodiments. The first dielectric pillar 505 and the second dielectric pillar 905 can be collectively referred to as a dielectric pillar 1305. As shown in FIG. 13, the material for the dielectric pillar 1305 can be deposited over the upper portion of the central portion 300.

Corresponding to operation 175, and still referring to FIG. 13, a first conductor structure 1310, a second conductor structure 1315, a third conductor structure 1320, and a fourth conductor structure 1325 (collectively referred to as conductor structures 1330) can be formed through the dielectric pillar 1305, to hook up the epitaxial structures. Specifically, the conductor structures 1330 are formed such that each of the conductor structures 1330 can be connected to the respective epitaxial structure. As shown in FIG. 13, the first epitaxial structure 210 is connected to the first conductor structure 1310, the second epitaxial structure 215 is connected to the second conductor structure 1315, the third epitaxial structure 220 is connected to the third conductor structure 1320, and the fourth epitaxial structure 225 is connected to the fourth conductor structure 1325.

To form the conductor structures 1330, a patternable layer (e.g., a photoresist material) can be formed over the surface of the semiconductor device 200. Such a patterned layer (not depicted) can define the portions where the conductor structures 1330 can be formed. The defined portions can be subsequently etched downward from the top surface of the semiconductor device 200 (or the 1305), through the top or side surface of the corresponding epitaxial structure. For example, the first and fourth conductor structures 1310, 1325 are connected to the top surface of the respective epitaxial structures 210, 225, and the second and third conductor structures 1315, 1320 are connected to the side wall of the respective epitaxial structures 215, 220.

The conductor structures 1330 may be formed of any metal conductor. Although depicted as one layer, the conductor structures 1330 may include one or more layers. For example, the conductor structures may include a first core layer for conducting and a second layer surrounding the first core layer for preventing diffusion (e.g., diffusion barrier). The dimensions of the conductor structures 1330 may be 40 nm to 200 nm in length (z-axis) and 30 nm to 60 nm in width (or diameter). The distances between the conductor structures 1310, 1315, 1320, 1325 may range from 2 nm to 10 nm. The shape, dimension, symmetry, etc. of the conductor structures 1330 described herein are merely a non-limiting example.

Referring to FIG. 13, the semiconductor device 200 can be operated as a complementary field effect transistor. For example, a first device 1335 (which is a bottom portion of the semiconductor device 200) may be a first device with a first conductivity, and a second device 1340 (which is a top portion of the semiconductor device 200) may be a second device with a second conductivity. For example, the first device 1335 may be a NMOS device, and the second device 1340 may be a PMOS device. For example, the first device 1335 may be a PMOS device, and the second device 1340 may be a NMOS device. In the first device 1335, the first epitaxial structure 210 can be a source structure, and the second epitaxial structure 215 can be a drain structure (or vice versa), while the first semiconductor structure 230 (e.g., silicon) and the first dopped semiconductor structure 260 (e.g., dopped silicon) can be a channel layer with the first gate structure 250 being a gate. Similarly, in the second device 1340, the third epitaxial structure 220 can be a source structure, and the fourth epitaxial structure 225 can be a drain structure (or vice versa), while the second semiconductor structure 235 (e.g., silicon) and the second dopped semiconductor structure 265 (e.g., dopped silicon) can be a channel layer with the second gate structure 255 being a gate. The source/drain structures (e.g., the epitaxial structures 210, 215, 220, and 225) can be connected at the top surface of the semiconductor device 200, by the conductor structures 1330 to control operation of the first device 1335 and the second device 1340.

Corresponding to operation 175, and referring to FIG. 13, the method 100 may end with the semiconductor device 200 shown in FIG. 13. As discussed above, the semiconductor device 200 is merely a non-limiting example device, and thus may include various structures. An example of the semiconductor device 200 that the method 100 has performed on may be a semiconductor device including a first epitaxial structure (e.g., 210) disposed below a dielectric pillar (e.g., 1305), a second epitaxial structure (e.g., 215) disposed above the first epitaxial structure and around the dielectric pillar, a third epitaxial structure (e.g., 220) disposed above the second epitaxial structure and around the dielectric pillar, and a fourth epitaxial structure (e.g., 225) disposed above the third epitaxial structure and around the dielectric pillar. The second and third epitaxial structures each may have a portion inwardly extending toward a central axis of the dielectric pillar.

In some examples, the semiconductor device may further include a first conductor structure (e.g., 1310) extending in a vertical direction through the dielectric pillar, a second conductor structure (e.g., 1315) extending in the vertical direction through the dielectric pillar, a third conductor structure (e.g., 1320) extending in the vertical direction through the dielectric pillar, and a fourth conductor structure (e.g., 1325) extending in the vertical direction. In some examples, the first conductor structure is in contact with the first epitaxial structure, the second conductor structure is in contact with the portion of the second epitaxial structure, the third conductor structure is in contact with the portion of the third epitaxial structure, and the fourth is in contact with the fourth epitaxial structure. In some examples, the portion of the second epitaxial structure has a first lateral distance and the portion of the third epitaxial structure has a second lateral distance, and wherein the first lateral distance is substantially greater than the second lateral distance. In some examples, the semiconductor device may further include a dielectric spacer (e.g., 605) disposed above the third epitaxial structure and around an upper portion of the dielectric pillar. In some examples, the dielectric spacer is surrounded by the fourth epitaxial structure.

In some examples, the semiconductor device may further include a first semiconductor structure (e.g., 230) surrounding the dielectric pillar and disposed between the first epitaxial structure and the second epitaxial structure, and a second semiconductor structure (e.g., 235) surrounding the dielectric pillar and disposed between the third epitaxial structure and the fourth epitaxial structure. In some examples, the semiconductor device may further include a first gate structure (e.g., 250) further surrounding the first semiconductor structure, and a second gate structure (e.g., 255) further surrounding the second semiconductor structure. In some examples, the first semiconductor structure, the first gate structure, the first epitaxial structure, and the second epitaxial structure collectively form a first transistor (e.g., 1335), and the second semiconductor structure, the second gate structure, the third epitaxial structure, and the fourth epitaxial structure collectively form a second transistor (e.g., 1340). In some examples, the first transistor has a first conductivity, and the second transistor has a second, opposite conductivity.

Another example of the semiconductor device 200 that the method 100 has performed on may be a semiconductor device including a first transistor (e.g., 1335) and a second transistor (e.g., 1340). The first transistor may include a first source/drain structure (e.g., 210) formed in a disc shape, and a second source/drain structure (e.g., 215) formed in a ring shape and disposed above the first source/drain structure. The second transistor may include a third source/drain structure (e.g., 220) formed in the ring shape and disposed above the second source/drain structure, and a fourth source/drain structure (e.g., 225) formed in the ring shape and disposed above the third source/drain structure. The second source/drain structure has a first inner radius, the third source/drain structure has a second inner radius, and the fourth source/drain structure has a third inner radius, and wherein the first inner radius is less than the second inner radius and the second inner radius is less than the third inner radius.

In some examples, the first transistor has a first conductivity (e.g., PMOS), and the second transistor has a second conductivity (e.g., NMOS) opposite to the first conductivity. In some examples, the first transistor may include a first channel structure (e.g., 230) formed in the ring shape and disposed between the first source/drain structure and the second source/drain structure, and the second transistor may include a second channel structure (e.g., 235) formed in the ring shape and disposed between the third source/drain structure and the fourth source/drain structure. In some examples, the first transistor may include a first gate structure (e.g., 250) formed in the ring shape and surrounding the first channel structure, and the second transistor may include a second gate structure (e.g., 255) formed in the ring shape and surrounding the second channel structure. In some examples, the semiconductor device may further include a first conductor structure (e.g., 1310) extending in a vertical direction to be in electrical connection with the first source/drain structure, a second conductor structure (e.g., 1315) extending in the vertical direction to be in electrical connection with the second source/drain structure, a third conductor structure (e.g., 1320) extending in the vertical direction to be in electrical connection with the third source/drain structure, and a fourth conductor structure (e.g., 1325) extending in the vertical direction to be in electrical connection with the fourth source/drain structure. In some examples, the first to fourth conductor structures are laterally spaced from one another. In some examples, the first to fourth source/drain structures are each an epitaxial structure.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first epitaxial structure disposed below a dielectric pillar;
a second epitaxial structure disposed above the first epitaxial structure and around the dielectric pillar;
a third epitaxial structure disposed above the second epitaxial structure and around the dielectric pillar; and
a fourth epitaxial structure disposed above the third epitaxial structure and around the dielectric pillar,
wherein the second and third epitaxial structures each have a portion inwardly extending toward a central axis of the dielectric pillar.

2. The semiconductor device of claim 1, further comprising:
a first conductor structure extending in a vertical direction through the dielectric pillar;
a second conductor structure extending in the vertical direction through the dielectric pillar;
a third conductor structure extending in the vertical direction through the dielectric pillar; and
a fourth conductor structure extending in the vertical direction.

3. The semiconductor device of claim 2, wherein the first conductor structure is in contact with the first epitaxial structure, the second conductor structure is in contact with the portion of the second epitaxial structure, the third conductor structure is in contact with the portion of the third epitaxial structure, and the fourth is in contact with the fourth epitaxial structure.

4. The semiconductor device of claim 2, wherein the portion of the second epitaxial structure has a first lateral distance and the portion of the third epitaxial structure has a second lateral distance, and wherein the first lateral distance is substantially greater than the second lateral distance.

5. The semiconductor device of claim 2, further comprising:
a dielectric spacer disposed above the third epitaxial structure and around an upper portion of the dielectric pillar.

6. The semiconductor device of claim 5, wherein the dielectric spacer is surrounded by the fourth epitaxial structure.

7. The semiconductor device of claim 1, further comprising:
a first semiconductor structure surrounding the dielectric pillar and disposed between the first epitaxial structure and the second epitaxial structure; and
a second semiconductor structure surrounding the dielectric pillar and disposed between the third epitaxial structure and the fourth epitaxial structure.

8. The semiconductor device of claim 7, further comprising:
a first gate structure further surrounding the first semiconductor structure; and
a second gate structure further surrounding the second semiconductor structure.

9. The semiconductor device of claim 8, wherein the first semiconductor structure, the first gate structure, the first epitaxial structure, and the second epitaxial structure collectively form a first transistor, and the second semiconductor structure, the second gate structure, the third epitaxial structure, and the fourth epitaxial structure collectively form a second transistor.

10. The semiconductor device of claim 9, wherein the first transistor has a first conductivity, and the second transistor has a second, opposite conductivity.

11. A semiconductor device, comprising:
a first transistor comprising:
a first source/drain structure formed in a disc shape; and
a second source/drain structure formed in a ring shape and disposed above the first source/drain structure; and
a second transistor comprising:
a third source/drain structure formed in the ring shape and disposed above the second source/drain structure; and
a fourth source/drain structure formed in the ring shape and disposed above the third source/drain structure,
wherein the second source/drain structure has a first inner radius, the third source/drain structure has a second inner radius, and the fourth source/drain structure has a third inner radius, and wherein the first inner radius is less than the second inner radius and the second inner radius is less than the third inner radius.

12. The semiconductor device of claim 11, wherein the first transistor has a first conductivity, and the second transistor has a second conductivity opposite to the first conductivity.

13. The semiconductor device of claim 11, wherein
the first transistor comprises:
a first channel structure formed in the ring shape and disposed between the first source/drain structure and the second source/drain structure; and
the second transistor comprises:
a second channel structure formed in the ring shape and disposed between the third source/drain structure and the fourth source/drain structure.

14. The semiconductor device of claim 13, wherein
the first transistor comprises:
a first gate structure formed in the ring shape and surrounding the first channel structure; and
the second transistor comprises:
a second gate structure formed in the ring shape and surrounding the second channel structure.

15. The semiconductor device of claim 11, further comprising:
a first conductor structure extending in a vertical direction to be in electrical connection with the first source/drain structure;
a second conductor structure extending in the vertical direction to be in electrical connection with the second source/drain structure;
a third conductor structure extending in the vertical direction to be in electrical connection with the third source/drain structure; and
a fourth conductor structure extending in the vertical direction to be in electrical connection with the fourth source/drain structure.

16. The semiconductor device of claim 15, wherein the first to fourth conductor structures are laterally spaced from one another.

17. The semiconductor device of claim 11, wherein the first to fourth source/drain structures are each an epitaxial structure.

18. A method for fabricating semiconductor devices, comprising:
forming a first epitaxial structure, a second epitaxial structure, a third epitaxial structure, and a fourth epitaxial structure spaced from one another along a vertical direction, each of the first to fourth epitaxial structure formed in a disc shape, wherein the first epitaxial structure is disposed below a first channel pillar, the second epitaxial structure is disposed above the first channel pillar and below the third epitaxial structure, the third epitaxial structure is disposed below a second channel pillar, and the fourth epitaxial structure is disposed above the second channel pillar;
removing a central portion of the first channel pillar and a central portion of the second channel pillar, thereby forming the second to fourth epitaxial structures each in a ring shape;
inwardly extending the second epitaxial structure;
inwardly extending the third epitaxial structure; and
forming a first conductor structure, a second conductor structure, a third conductor structure, and a fourth conductor structure to be in contact with the first epitaxial structure, the second epitaxial structure, the third epitaxial structure, and the fourth epitaxial structure, respectively, wherein each of the first to fourth conductor structures extends along the vertical direction.

19. The method of claim 18, prior to the step of inwardly extending the second epitaxial structure, further comprising:
forming a dielectric pillar to overlay the first epitaxial structure and cover an inner sidewall of the second epitaxial structure;
forming a first dielectric spacer to cover respective inner sidewalls of the third epitaxial structure and the fourth epitaxial structure; and
removing a portion of the dielectric pillar to expose the inner sidewall of the second epitaxial structure.

20. The method of claim 19, following the step of inwardly extending the second epitaxial structure and prior to the step of inwardly extending the third epitaxial structure, further comprising:
removing the first dielectric spacer;
extending the dielectric pillar to cover the respective inner sidewalls of the third epitaxial structure and the fourth epitaxial structure;
removing another portion of the dielectric pillar to expose the inner sidewall of the fourth epitaxial structure;
forming a second dielectric spacer to cover the inner sidewall of the fourth epitaxial structure; and
removing yet another portion of the dielectric pillar to expose the inner sidewall of the third epitaxial structure.
